(19) United States
(12) Patent Application Publication
(10) Pub. No.: US 2025/0327880 A1
(43) Pub. Date: Oct. 23, 2025

(54) TESTING APPARATUS

(71) Applicant: Johnson Controls Tyco IP Holdings LLP, Milwaukee, WI (US)

(72) Inventors: Amit KUMAR, Milwaukee, WI (US); Manoj Mohan OJHA, Milwaukee, WI (US); Faruk MEAH, Milwaukee, WI (US); Steven BENNETT, Milwaukee, WI (US); Vishal BHOSALE, Milwaukee, WI (US)

(21) Appl. No.: 18/855,995

(22) PCT Filed: Apr. 13, 2023
(86) PCT No.: PCT/US2023/065712

§ 371 Date: Oct. 10, 2024

(30) Foreign Application Priority Data
Apr. 19, 2022 (IN) 202211023056

(51) Int. Cl. G01R 31/68

(52) U.S. Cl. CPC G01R 31/68

(57) ABSTRACT

The present application is direction to a testing apparatus for use with a fire detection system having a plurality of base units. The testing apparatus comprises: one or more connectors, each of the connectors configured to be connected to a corresponding base terminal of a base unit; one or more first testers, wherein each of the first testers is configured to receive a voltage from a corresponding connector; a selector having a plurality of selectable configurations, each of the configurations defining a testing mode of the testing apparatus. Each of the first testers is configured to provide an output based on the configuration of the selector and the received voltage, the output indicating the connection state of a base terminal connected to the corresponding connector.

### CROSS-REFERENCE TO RELATED APPLICATIONS

This application claims priority to Indian Provisional Application No. 202211023056 titled “TESTING APPARATUS,” filed Apr. 19, 2022, which is assigned to the assignee hereof, and incorporated herein by reference in their entirety.

### TECHNICAL FIELD

The present invention relates to a testing apparatus for use with a fire detection system.

### BACKGROUND TO THE INVENTION AND PRIOR ART

Fire detection systems often include a control panel and a number of networked devices connected to the control panel by network wiring. Such systems normally include multiple bases which are all connected to the network wiring to which the networked devices are mounted. Wiring faults are common during installation of such systems. A common mistake is incorrect wiring polarities connected to incorrect terminals on a base. In addition, there are several different types of base such as standard bases, isolator bases, and functional bases. All of these types of bases require different wiring connections, which further increases the chance of mistakes occurring. Most of the time, wiring issues are detected at the time of commissioning and it takes a lot of time and effort to locate the issue. Currently, multi-meters are the only common tool available to installers to tackle such issues.

### SUMMARY OF INVENTION

According to an aspect of the present invention, there is provided a testing apparatus for use with a fire detection system having a plurality of base units. The testing apparatus comprises: one or more connectors, each of the connectors configured to be connected to a corresponding base terminal of a base unit; one or more first testers, wherein each of the first testers is configured to receive a voltage from a corresponding connector; a selector having a plurality of selectable configurations, each of the configurations defining a testing mode of the testing apparatus. Each of the first testers is configured to provide an output based on the configuration of the selector and the received voltage, the output indicating the connection state of a base terminal connected to the corresponding connector.

The testing apparatus may comprise one or more second testers. Each of the second testers is configured to receive a voltage from a corresponding connector and provide an output independently of the configuration of the selector and based on the received voltage, the output indicating the connection state of a base terminal connected to the corresponding connector.

The testing apparatus may comprise one or more first indicators. Each of the first indicators is configured to receive the output from a corresponding tester and provide, based on the output, an indication of the connection state of the base terminal.

At least one of the first indicators may comprise one or more light sources.

At least one of the first indicators may comprise a first light source configured to output light of a first colour and a second light source configured to output light of a second colour. The first light source is configured to output light based on the output received from the tester indicating that the connection state is a first connection state, and the second light source is configured to output light based on the output received from the tester indicating that the connection state is a second connection state.

The selector may comprise a switch having a plurality of selectable positions. Each of the first testers may be configured to provide an output based on the position of the switch.

The testing apparatus may comprise a voltage monitor configured to detect a voltage of wiring to which the base unit is connected and provide an output indicating whether the voltage falls within a predetermined range.

The testing apparatus may comprise a fault detector configured to receive, from each of the testers, a second output indicating the connection state of the corresponding base terminal and, from the voltage monitor, an output indicating the voltage, and to provide, based on the received outputs, an output indicating whether a fault is present in the wiring or the connections of the base terminals.

The testing apparatus may comprise a second indicator configured to receive the output from the fault detector, and to provide, based on the output received from the fault detector, an indication of whether a fault is present in the wiring or the connections of the base terminals.

The second indicator may comprise one or more light sources.

The second indicator may comprise a third light source configured to output light of a third colour and a fourth light source configured to output light of a fourth colour. The third light source is configured to output light based on the output indicating that a fault is present, and the fourth light source is configured to output light based on the output indicating that no fault is present.

The second indicator may comprise a sound output device.

The sound output device may be configured to output a sound based on the output indicating that a fault is present.

The testing apparatus may further comprise a power input configured to receive power from one or more of the connectors and provide power for the testing apparatus.

The testing apparatus may further comprise a power source configured to generate power for the testing apparatus.

According to another aspect of the present invention, there is provided a testing apparatus for use with a fire detection system having a plurality of base units. The testing apparatus comprises one or more connectors, each of the connectors configured to be connected to a corresponding base terminal of a base unit; and one or more testers. Each of the testers is configured to receive a voltage from a corresponding connector and provide an output based on the received voltage, the output indicating the connection state of a base terminal connected to the corresponding connector.

Further features and aspects of the invention will be apparent from the appended claims.

### BRIEF DESCRIPTION OF THE DRAWINGS

Further features and advantages of the present invention will become apparent from the following description, presented by way of example only, and by reference to the drawings, wherein like reference numerals refer to like parts, and wherein:

FIG. 1 is a schematic diagram of a testing apparatus according to embodiments;

FIGS. 2A-2C are schematic diagrams of different bases;

FIG. 3 is a block diagram of a testing apparatus according to embodiments;

FIG. 4 is a circuit diagram of a tester according to embodiments;

FIG. 5 is a circuit diagram of a switch according to embodiments; and

FIG. 6 is a circuit diagram of a tester according to embodiments.

### DESCRIPTION OF THE EMBODIMENTS

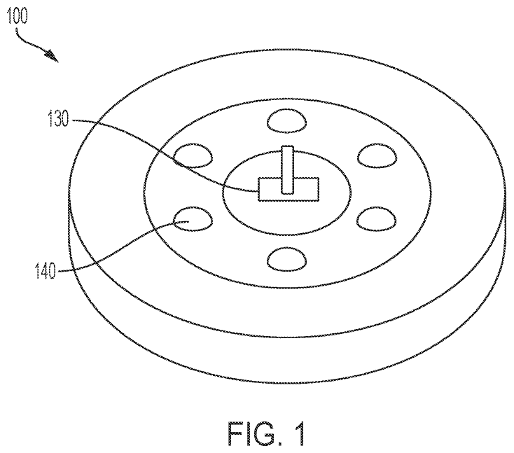

FIG. 1 is a schematic diagram of a testing apparatus for testing the correct wiring of a base of a fire alarm system. Such a fire alarm system includes: a control panel (sometimes known as control & indicating equipment (CIE); addressable networked wiring extending from the control panel, the wiring including two lines: a positive line and a negative line; multiple bases (or base units) which are wired to the addressable network wiring and which include a plurality of terminals; and a number of addressable networked devices attached to the bases. It should be understood that the testing apparatus may also be used with fire alarm systems including networked wiring which is not addressable.

Once attached to a base, the networked device connects to the terminals of the base so as to be addressable by the control panel. For a new system, the wiring is installed first, extending from the location at which the control panel will be installed to the locations at which the addressable networked devices (smoke detectors, fire detectors, call points, notification devices, and the like) will be installed. In the embodiments described, the wiring is connected in a loop, with the ends connected together. The bases are then wired to the addressable networked wiring in the locations at which the addressable networked devices will be installed during the commissioning of the system. It should be noted that there is more than one type of base, and in this system, there are three different types of base, depending on the system specification. Once the bases have been wired in, the testing apparatus of the present invention can be connected to each base in turn to test whether it has been correctly wired, and to indicate the result of the test. The commissioning of the system happens later.

The testing apparatus 100 shown in FIG. 1 includes a switch 130 which can switch the apparatus between different testing modes. The testing apparatus 100 also includes six indicators 140, each of which includes a multi-colour LED. In the present example, each of the LEDs can output either green light or red light.

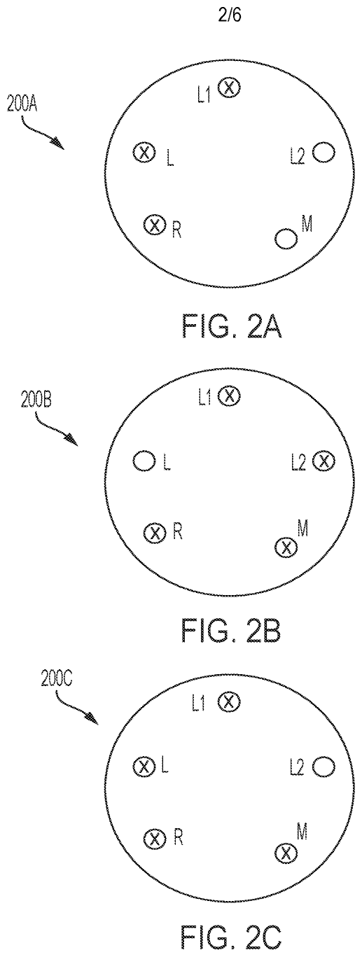

The testing apparatus 100 is a portable device, and has a structure which is designed to be attached to various types of bases, such as those described below in relation to FIGS. 2A-2C. Five of the indicator LEDs 140 output green light to indicate that a corresponding terminal on a given base is connected correctly. The sixth indicator LED 140 outputs green light when all of the terminals are connected correctly and the loop voltage is within a certain range. Hence, the testing apparatus can provide a user with direct indication of connection quality for multiple types of bases.

FIGS. 2A-2C shows examples of bases (or base units) which may be used with the testing apparatus of the present invention. Each base has five terminals (or base terminals), and only some of these may be connected in use. The terminals which are typically connected in use are indicated by an ‘X’.

FIG. 2A shows an example of a base without an isolator (referred to as a “non-isolator base”). For this type of base, terminal “L” is connected to the negative line of the networked wiring, and terminal “L1” is connected to the positive line of the networked wiring. Terminals “L2” and “M” are not wired. Terminal “R” is wired only if a remote indicator is required.

FIG. 2B shows an example of a base including an isolator (referred to as an “isolator base”). For this type of base, terminal “L” is not wired. Terminal “L1” is connected to the positive line of the networked wiring. Terminals “L2” and “M” are connected to the negative line of the networked wiring. Terminal “R” is wired only if a remote indicator is required.

FIG. 2C shows an example of a continuity base. For this type of base, terminals “L” and “M” are connected to the negative line of the networked wiring, and terminal “L1” is connected to the positive line of the networked wiring. Terminal “R” is wired only if a remote indicator is required.

Table 1 below summarizes the correct connection of each terminal for each type of base.

| Base | Correct Functions for Different Bases | | |
|---|---|---|---|
| Terminal | Non-isolator | Isolator | Continuity |
| Terminal | Positive Line | Positive Line | Positive Line |
| L1 | In & Out | In & Out | In & Out |
| | (Loop + VE) | (Loop + VE) | (Loop + VE) |
| Terminal | Negative Line | Not Used | Negative Line |
| L | In & Out | (Floating) | In & Out |
| | (Loop − VE) | | (Loop − VE) |
| Terminal | Must Not Be Wired | Negative Line | Must Not Be Wired |
| L2 | (Floating) | Isolator In & Out | (Floating) |
| | | (Loop − VE) | |
| Terminal | Must Not Be Wired | Negative Line | Negative Line |
| M | (Floating) | Isolator In & Out | In & Out |
| | | (Loop − VE) | (Loop − VE) |
| Terminal | Remote LED Out, | Remote LED Out, | Remote LED Out, |
| R | wired only if | wired only if | wired only if |
| | remote indicator | remote indicator | remote indicator |
| | is required | is required | is required |

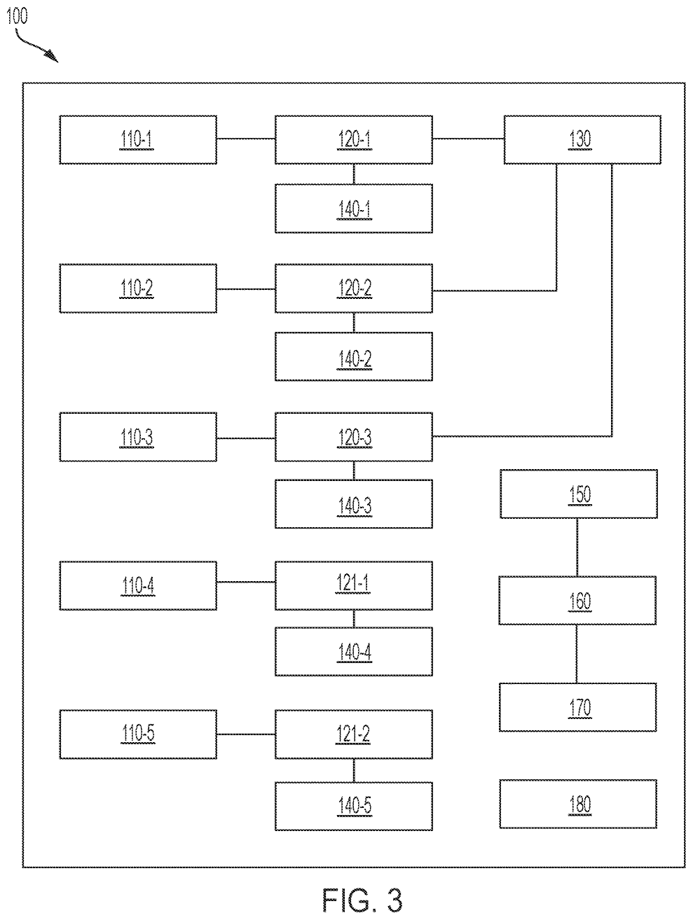

FIG. 3 is a block diagram showing a testing apparatus. The testing apparatus 100 includes five connectors 110-1 to 110-5, three first testers 120-1 to 120-3, and a selector 130. In the present example, the testing apparatus 100 also includes two second testers 121-1 and 121-2, as well as a voltage monitor 150, a fault detector 160 and a second indicator 170.

Each of the connectors 110 is configured to be connected to a corresponding terminal of a base unit. In the present example, the connector 110-1 is connected to the “L” terminal, connector 110-2 is connected to the “L2” terminal and connector 110-3 is connected to the “M” terminal. The connector 110-4 is connected to the “L1” terminal and the connector 110-5 is connected to the “R” terminal.

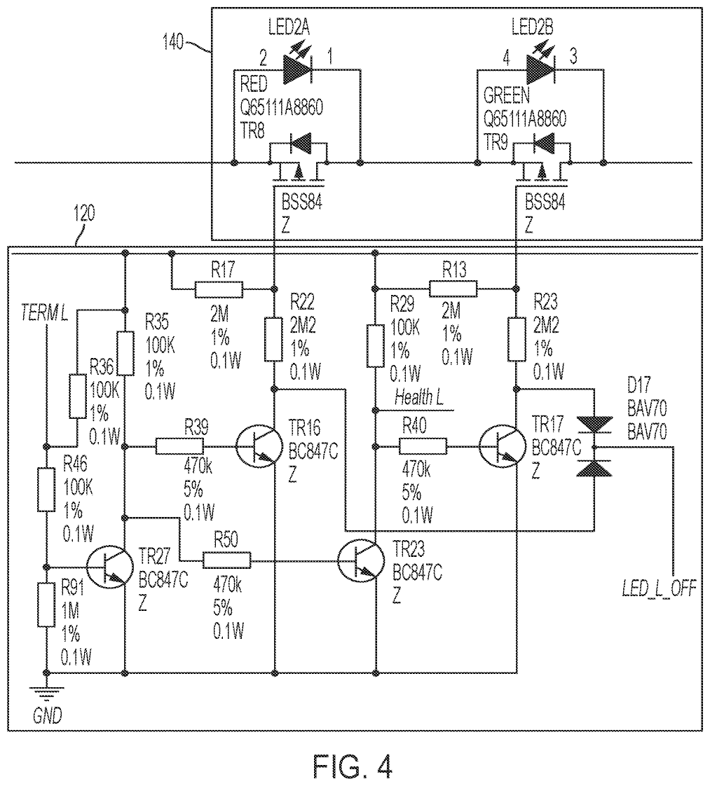

Each of the first testers 120 is connected to a corresponding connector 110 so as to receive a voltage from the corresponding connector 110. For example, the first tester 120-1 is connected to the connector 110-1. The first testers 120 may be implemented as circuits. An example of such a circuit is shown in FIG. 4 below.

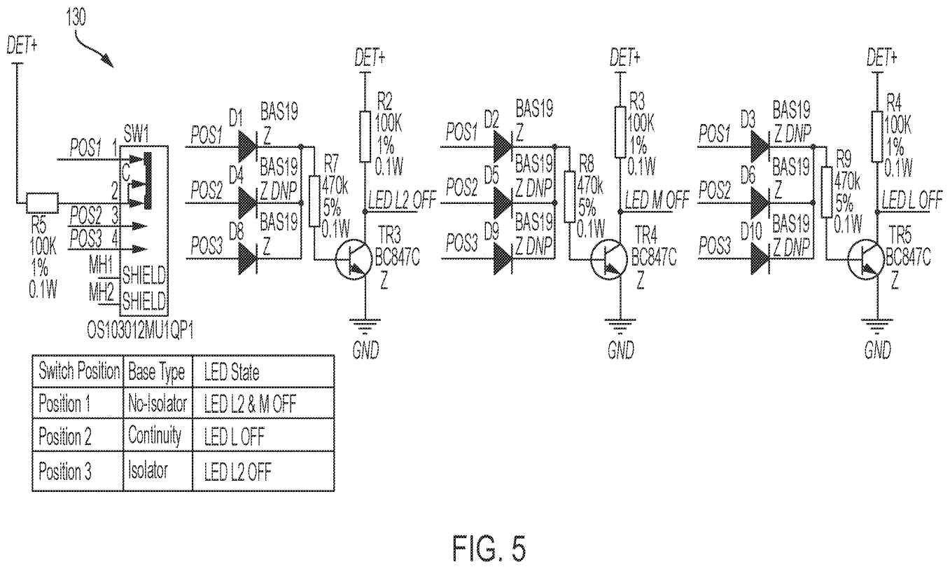

The selector 130 has a plurality of selectable configurations. Each of the configurations defines a testing mode of the testing apparatus 100. Each testing mode may correspond to a type of base (e.g. non-isolator, isolator or continuity). In the present embodiment, the selector 130 is a switch which has three selectable positions. Each of the positions corresponds to a different type of base. An example of a switch circuit is shown in FIG. 5 below.

Each of the first testers 120 is configured to provide an output. The output from each first tester 120 depends on the testing mode of the testing apparatus 100, as well as the voltage the first tester 120 receives from the base terminal via the corresponding connector 110. The output from each first tester 120 indicates the connection state of the base terminal (i.e. whether the base terminal is correctly connected or incorrectly connected). Hence, the testing apparatus can test the connection states of base terminals on multiple types of bases.

As described above in relation to FIGS. 2A-2C, certain base terminals are not connected for certain types of base. For example, the “L” terminal is not connected for an isolator base, but is connected for non-isolator and continuity bases.

When the testing apparatus 100 is in an isolator base testing mode, tester 120-1 connected to the “L” terminal (via the connector 110-1) will not produce any output. However, when the testing apparatus 100 is in a non-isolator base testing mode or a continuity base testing mode, tester 120-1 which is connected to the “L” terminal will produce an output according to the voltage the tester 120-1 receives from the “L” terminal. The output indicates the connection state of the “L” terminal, i.e. whether the “L” terminal is correctly connected or incorrectly connected.

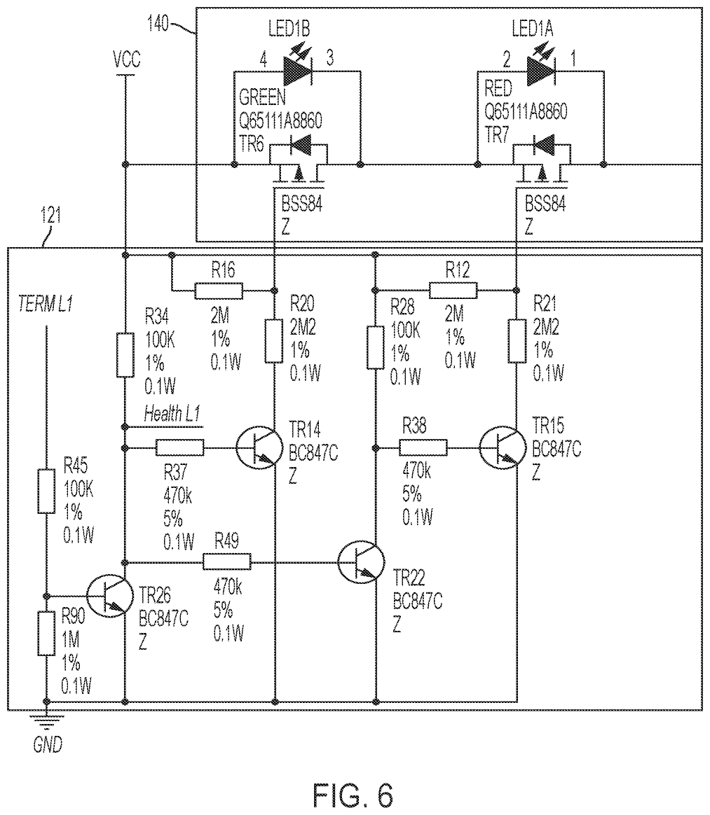

Each of the second testers 121 is connected to a corresponding connector 110 so as to receive a voltage from the corresponding connector 110. As shown in FIG. 3, the second tester 121-1 is connected to the connector 110-4 and the second tester 121-2 is connected to the connector 110-5. The second tester 121 may be implemented as circuits. An example of such a circuit is shown in FIG. 6 below.

Each of the second testers 121 is configured to provide an output. The output from each second tester 121 depends on the voltage the second tester 121 receives from the base terminal via the corresponding connector 110. Each of the second testers 121 is configured to be connected to a base terminal which is connected for all types of base, such as the “L1” terminal. Hence, the output from each second tester 121 is independent of the testing mode of the testing apparatus 100. The output from each second tester 120 indicates the connection state of the base terminal (i.e. whether the base terminal is correctly connected or incorrectly connected).

Each of the first indicators 140 is configured to receive the output from a corresponding one of the first testers 120 or second testers 121. For example, the first indicator 140-1 is configured to receive the output from the first tester 120-1.

Each of the first indicators 140 is configured to provide, based on the output from the corresponding tester, an indication of the connection state of the base terminal which is connected to the corresponding tester. In some embodiments, the first indicators 140 include one or more light sources, such as LEDs. This allows the testing apparatus 100 to provide a user with a visual indication of the connection states of the base terminals.

In the present embodiment, each of the first indicators 140 comprises a first LED (not shown) configured to output red light, and a second LED (not shown) configured to output green light. In other embodiments, the LEDs may be configured to output other colours of light.

The first LED is configured to output red light based on the output received from the corresponding tester indicating that the base terminal is incorrectly connected (e.g. the polarity of the voltage received from the base terminal is incorrect, or the base terminal is floating). This provides a user with a visual indication that the base terminal is incorrectly connected.

The second LED is configured to output green light based on the output received from the corresponding tester indicating that the base terminal is correctly connected. This provides a user with a visual indication that the base terminal is correctly connected.

The testing apparatus 100 also includes a voltage monitor 150 configured to detect a voltage of the wiring to which the base unit is connected. The voltage monitor 150 receives the voltage from one or more of the base terminals via the corresponding connectors 110. Connections between the voltage monitor 150 and the connectors 110 are not shown in FIG. 3 for clarity. The voltage monitor 150 is configured to provide an output indicating whether the voltage falls within a predetermined range.

The testing apparatus 100 also includes a fault detector 160. The fault detector 160 is connected to each of the first and second testers 120, 121, and is configured to receive, from each of the first and second testers 120, 121, an output indicating the connection state of the base terminal connected to the corresponding tester. This output may be the same or different as the outputs provided from the first and second testers 120, 121 to the first indicators 140. Connections between the fault detector 160 and the first and second testers 120, 121 are not shown in FIG. 3 for clarity.

The fault detector 160 is also connected to the voltage monitor 150, and is configured to receive the output from the voltage monitor 150. The fault detector 160 is configured to provide, based on the outputs received from the first and second testers 120, 121 and the voltage monitor 150, an output indicating whether a fault is present in the wiring, or the connections of the base terminals.

The testing apparatus 100 also includes a second indicator 170 configured to receive the output from the fault detector 160, and to provide, based on the output received from the fault detector 160, an indication of whether a fault is present in the wiring or the connections of the base terminals. In some embodiments, the second indicator 170 comprises one or more light sources, such as LEDs. This allows the testing apparatus 100 to provide a user with a visual indication of whether a fault is present.

In the present embodiment, the second indicator 170 comprises a first LED (not shown) configured to output red light, and a second LED (not shown) configured to output green light. In other embodiments, the LEDs may be configured to output other colours of light.

The first LED is configured to output red light based on the output received from the fault detector 160 indicating that a fault is present. This provides a user with a visual indication that there is a fault present in the system.

The second LED is configured to output green light based on the output received from the fault detector 160 indicating that no fault is present. This provides a user with a visual indication that the system is operating correctly.

In some embodiments, the second indicator comprises a sound output device, such as a buzzer, which is configured to output a sound based on the output received from the fault detector indicating that a fault is present. The second indicator may comprise a sound output device alternatively or in addition to the one or more light sources. In the present embodiment, the second indicator 170 comprises a buzzer in addition to the first and second LEDs.

In the present embodiment, the testing apparatus 100 comprises a power input 180 configured to receive power from one or more of the base terminals via the connectors 110 and provide power for the testing apparatus. For example, the power input 180 may supply power for driving the indicators 140.

In other embodiments, the testing apparatus 100 may include its own independent power source (not shown), such as a battery. This allows the testing apparatus 100 to be powered independently from the networked wiring.

FIG. 4 shows an example of a tester circuit and a corresponding indicator circuit. In this example, the tester circuit 120 is configured to receive an input voltage, TERM_L, from the “L” terminal via a corresponding connector (not shown). The operating principles of the tester circuit may be applied to tester circuits configured to receive input voltages from other terminals such as the “L2” and “M” terminals.

When the testing apparatus is in a non-isolator base testing mode or a continuity base testing mode, the tester circuit 120 will produce an output according to the input voltage TERM_L. The output of the tester circuit 120 drives the indicator circuit 140.

The tester circuit 120 includes various components, in particular four transistors TR16, TR17, TR27 and TR23. The indicator circuit 140 includes a red LED, LED 2A, and a green LED, LED 2B. The on/off states of LED 2A and LED 2B are dependent on the on/off states of MOSFETs TR8 and TR9 respectively.

If TERM_L either remains floating or connected to the positive line, then transistor TR27 will be on, and hence transistor TR16 and MOSFET TR8 will be off and LED 2A will be on. Transistor TR23 will be off, hence transistor TR17 and MOSFET TR9 will be on and LED 2B will be off.

If TERM_L is connected to the negative line, then transistor TR27 will be off, and hence transistor TR16 and MOSFET TR8 will be on and LED 2A will be off. Transistor TR23 will be on, hence transistor TR17 and MOSFET TR9 will be off and LED 2B will be on.

When the testing apparatus is in an isolator base testing mode, the LEDs 2A, 2B will be off. This is explained in detail below with reference to FIG. 5.

FIG. 5 shows an example of a switch circuit which can be switched between a first position corresponding to a non-isolator base testing mode, a second position corresponding to an isolator base testing mode and a third position corresponding to a continuity base testing mode.

The switch circuit includes three transistors TR3, TR4, TR5. When the switch is in position 2, an isolator base testing mode is selected. In this case, transistor TR5 is on, which turns on MOSFETs TR8 and TR9 shown in FIG. 4, hence by-passing LEDs 2A and 2B. Hence the LEDs for the tester circuit 140 shown in FIG. 4 will be off when the switch is in position 2.

FIG. 6 shows an example of a tester circuit and a corresponding indicator circuit. In this example, the tester circuit 121 is configured to receive an input voltage, TERM_L1, from the “L1” terminal via a corresponding connector (not shown). The operating principles of the tester circuit may be applied to tester circuits configured to receive input voltages from other terminals such as the “R” terminal.

The tester circuit 121 includes various components, in particular four transistors TR14, TR15, TR22 and TR26. The output of the tester circuit 121 drives the indicator circuit 140. The indicator circuit 140 includes a red LED, LED 1A, and a green LED, LED 1B. The on/off states of LED 1A and LED 1B are dependent on the on/off states of MOSFETs TR7 and TR6 respectively.

If TERM_L1 either remains floating or connected to the negative line, then transistor TR26 will be off, and hence transistor TR14 and MOSFET TR6 will be on and LED 1B will be off. Transistor TR22 will be on, hence transistor TR15 and MOSFET TR7 will be off and LED 1A will be ON.

If TERM_L1 is connected to the positive line, then transistor TR26 will be on, and hence transistor TR14 and MOSFET TR6 will be off and LED 1B will be on. Transistor TR22 will be off, hence transistor TR15 and MOSFET TR7 will be on and LED 1A will be off.

Various further modifications to the above described examples, whether by way of addition, deletion or substitution, will be apparent to the skilled person to provide additional examples, any and all of which are intended to be encompassed by the appended claims.

1. A testing apparatus for use with a fire detection system having a plurality of base units, the testing apparatus comprising:
one or more connectors, each of the connectors configured to be connected to a corresponding base terminal of a base unit;
one or more first testers, wherein each of the first testers is configured to receive a voltage from a corresponding connector; and
a selector having a plurality of selectable configurations, each of the configurations defining a testing mode of the testing apparatus;
wherein each of the first testers is configured to provide an output based on the configuration of the selector and the received voltage, the output indicating the connection state of a base terminal connected to the corresponding connector.

2. A testing apparatus according to claim 1, comprising:
one or more second testers, wherein each of the second testers is configured to receive a voltage from a corresponding connector and provide an output independently of the configuration of the selector and based on the received voltage, the output indicating the connection state of a base terminal connected to the corresponding connector.

3. A testing apparatus according to claim 1, comprising:
one or more first indicators, wherein each of the first indicators is configured to receive the output from a corresponding tester and provide, based on the output, an indication of the connection state of the base terminal.

4. A testing apparatus according to claim 1, wherein at least one of the first indicators comprises one or more light sources.

5. A testing apparatus according to claim 4, wherein at least one of the first indicators comprises a first light source configured to output light of a first colour and a second light source configured to output light of a second colour,
wherein the first light source is configured to output light based on the output received from the tester indicating that the connection state is a first connection state, and the second light source is configured to output light based on the output received from the tester indicating that the connection state is a second connection state.

6. A testing apparatus according to claim 1, wherein the selector comprises a switch having a plurality of selectable positions, and each of the first testers is configured to provide an output based on the position of the switch.

7. A testing apparatus according to claim 1, comprising a voltage monitor configured to detect a voltage of wiring to which the base unit is connected and provide an output indicating whether the voltage falls within a predetermined range.

8. A testing apparatus according to claim 1, comprising a fault detector configured to receive, from each of the testers, a second output indicating the connection state of the corresponding base terminal and, from the voltage monitor, an output indicating the voltage, and
to provide, based on the received outputs, an output indicating whether a fault is present in the wiring or the connections of the base terminals.

9. A testing apparatus according to claim 8, comprising a second indicator configured to receive the output from the fault detector, and
to provide, based on the output received from the fault detector, an indication of whether a fault is present in the wiring or the connections of the base terminals.

10. A testing apparatus according to claim 9, wherein the second indicator comprises one or more light sources.

11. A testing apparatus according to claim 10, wherein the second indicator comprises a third light source configured to output light of a third colour and a fourth light source configured to output light of a fourth colour,
wherein the third light source is configured to output light based on the output indicating that a fault is present, and the fourth light source is configured to output light based on the output indicating that no fault is present.

12. A testing apparatus according to claim 9, wherein the second indicator comprises a sound output device.

13. A testing apparatus according to claim 12, wherein the sound output device is configured to output a sound based on the output indicating that a fault is present.

14. A testing apparatus according to claim 1, further comprising a power input configured to receive power from one or more of the connectors and provide power for the testing apparatus.

15. A testing apparatus according to claim 1, further comprising a power source configured to generate power for the testing apparatus.

16. A testing apparatus for use with a fire detection system having a plurality of base units, the testing apparatus comprising:
one or more connectors, each of the connectors configured to be connected to a corresponding base terminal of a base unit; and
one or more testers, wherein each of the testers is configured to receive a voltage from a corresponding connector and provide an output based on the received voltage, the output indicating the connection state of a base terminal connected to the corresponding connector.
